(19) United States
(12) Patent Application Publication
(10) Pub. No.: US 2024/0307925 A1
(43) Pub. Date: Sep. 19, 2024

(54) SUBSTRATE PROCESSING METHOD AND SUBSTRATE PROCESSING SYSTEM

(71) Applicant: Tokyo Electron Limited, Tokyo (JP)

(72) Inventors: Yoshitomo Sato, Koshi-shi, Kumamoto (JP); Osamu Miyahara, Koshi-shi, Kumamoto (JP)

(21) Appl. No.: 18/459,913

(22) PCT Filed: Feb. 17, 2022
(86) PCT No.: PCT/JP2022/006285

§ 371 Date: Sep. 1, 2023

(30) Foreign Application Priority Data
Mar. 3, 2021 (JP) 2021-033510

(51) Int. Cl. B08B 1/12; B08B 3/02

(52) U.S. Cl. CPC B08B 1/12; B08B 3/02

(57) ABSTRACT

A substrate processing method includes etching a film formed on a rear surface of a substrate opposite to a main surface of the substrate and polishing the rear surface of the substrate after the etching of the film. In the etching of the film, a film formed on a rear surface of a substrate opposite to a main surface of the substrate is etched. In the polishing of the rear surface, the rear surface of the substrate is polished after the etching.

### TECHNICAL FIELD

The various aspects and embodiments described herein pertain generally to a substrate processing method and a substrate processing system.

### BACKGROUND

Various processings on a substrate, such as a semiconductor wafer or a glass substrate, are performed while the substrate is held by a substrate holder. In this case, a rear surface of the substrate opposite to a main surface of the substrate comes into contact with the substrate holder, and, thus, a particle may adhere to the rear surface of the substrate or a burr may be generated on the rear surface of the substrate.

In this regard, there has been known a method of removing a foreign substance, such as the particle or burr, from the rear surface of the substrate by performing a cleaning processing or a polishing processing on the rear surface of the substrate with a brush.

### PRIOR ART DOCUMENT

Patent Document 1: Japanese Patent Laid-open Publication No. 2013-021026

### DISCLOSURE OF THE INVENTION

### Problems to be Solved by the Invention

In view of the foregoing, the present disclosure provides a technique capable of appropriately removing a foreign substance from a rear surface of a substrate on which a film has been formed.

### Means for Solving the Problems

In an exemplary embodiment, a substrate processing method includes etching a film formed on a rear surface of a substrate opposite to a main surface of the substrate and polishing the rear surface of the substrate after the etching of the film. In the etching of the film, a film formed on a rear surface of a substrate opposite to a main surface of the substrate is etched. In the polishing of the rear surface, the rear surface of the substrate is polished after the etching.

### Effects of the Invention

According to the present disclosure, it is effective in appropriately removing the foreign substance from the rear surface of the substrate on which the film has been formed.

### BRIEF DESCRIPTION OF THE DRAWINGS

FIG. 1 is a plan view schematically illustrating a substrate processing system according to an exemplary embodiment.

FIG. 2 is a side view schematically illustrating the substrate processing system according to the exemplary embodiment.

FIG. 3 shows a configuration of a wafer according to the exemplary embodiment.

FIG. 4 is a diagram schematically illustrating a first processing unit according to the exemplary embodiment.

FIG. 5 is a plan view schematically illustrating a second processing unit according to the exemplary embodiment.

FIG. 6 is a side view schematically illustrating the second processing unit according to the exemplary embodiment.

FIG. 7 is a flowchart illustrating a sequence of substrate processings performed by the substrate processing system according to the exemplary embodiment.

FIG. 8A is a diagram illustrating an example of the operation of the first processing unit.

FIG. 8B is a diagram illustrating an example of the operation of the first processing unit.

FIG. 9A is a diagram illustrating an example of an operation of the second processing unit.

FIG. 9B is a diagram illustrating an example of the operation of the second processing unit.

FIG. 9C is a diagram illustrating an example of the operation of the second processing unit.

FIG. 9D is a diagram illustrating an example of the operation of the second processing unit.

FIG. 10 is a diagram describing improvement of a particle removal rate by a substrate processing method according to the exemplary embodiment.

FIG. 11 is a plan view schematically illustrating a substrate processing system according to a modification example of the exemplary embodiment.

### DETAILED DESCRIPTION

Hereinafter, exemplary embodiments of a substrate processing method and a substrate processing system according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships and different ratios.

A film may be formed on a rear surface of a substrate for various purposes. In the above-described conventional technique, it is not considered to remove a foreign substance from the rear surface of the substrate on which the film has been formed. For example, when a cleaning processing is performed on the rear surface of the substrate with a brush as in the conventional technique, it is difficult to remove a particle buried in the film on the rear surface of the substrate. Also, when a polishing processing is performed on the rear surface of the substrate, the rear surface of the substrate may be damaged by a particle buried in the film on the rear surface of the substrate or a particle adhering to the rear surface of the substrate, which may cause generation of a new burr. Therefore, a technique is expected that is capable of appropriately removing the foreign substance from the rear surface of the substrate on which the film has been formed.

### <Configuration of Substrate Processing System>

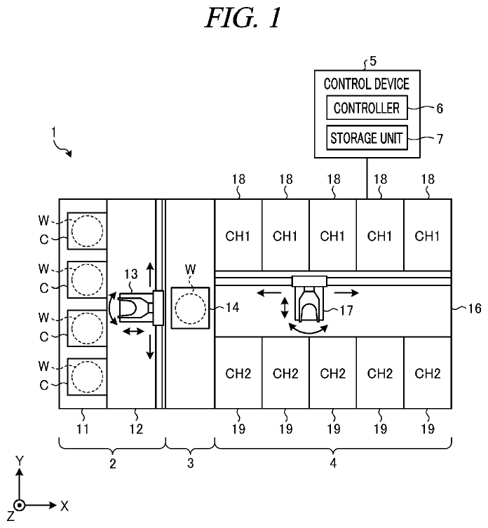

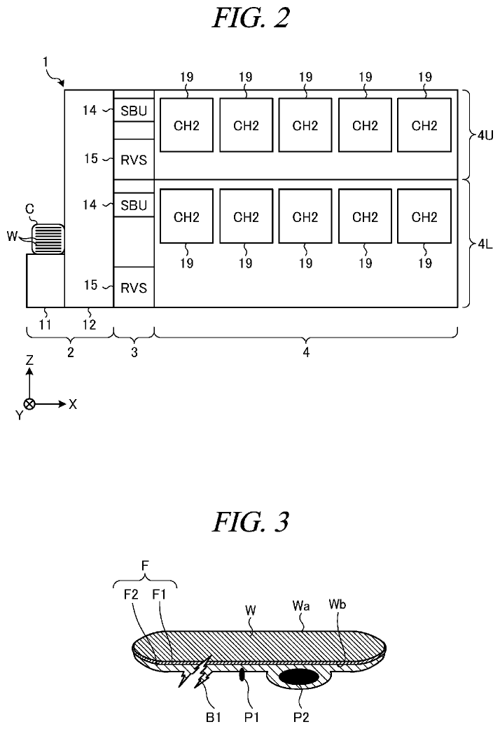

First, a configuration of a substrate processing system 1 according to an exemplary embodiment will be described with reference to FIG. 1 and FIG. 2. FIG. 1 is a plan view schematically illustrating the substrate processing system 1 according to the exemplary embodiment. FIG. 2 is a side view schematically illustrating the substrate processing system 1 according to the exemplary embodiment. Hereinafter, an X-axis, a Y-axis, and a Z-axis that are orthogonal to one another are specified in order to clarify a positional relationship where a positive direction of the Z-axis is provided as a vertically upward direction.

As illustrated in FIG. 1, the substrate processing system 1 according to the exemplary embodiment is equipped with a carry-in/out station 2, a delivery station 3, and a processing station 4 which are arranged in this order.

In this substrate processing system 1, a substrate, i.e., a semiconductor wafer (hereinafter, referred to as “wafer W”) in the present exemplary embodiment carried from the carry-in/out station 2 is transferred into the processing station 4 via the delivery station 3, and processed in the processing station 4. Further, in the substrate processing system 1, the wafer W after being processed is returned back into the carry-in/out station 2 from the processing station 4 via the delivery station 3, and sent to the outside from the carry-in/out station 2.

The carry-in/out station 2 is equipped with a cassette placing section 11 and a transfer section 12. A plurality of cassettes C each of which accommodates a plurality of wafers W therein horizontally is placed in the cassette placing section 11.

The transfer section 12 is provided between the cassette placing section 11 and the delivery station 3, and has a first transfer device 13 therein. The first transfer device 13 is equipped with a plurality of (for example, five) wafer holders each of which is configured to hold a single sheet of wafer W.

The first transfer device 13 is configured to be movable horizontally and vertically and pivotable around a vertical axis and to transfer a plurality of wafers W between the cassette C and the delivery station 3 at the same time with the plurality of wafer holders.

Now, the delivery station 3 will be described. As illustrated in FIG. 2, a plurality of substrate placing units (SBU) 14 and a plurality of inverting mechanisms (RVS) 15 are provided inside the delivery station 3. Specifically, two substrate placing units 14 are respectively placed at a position corresponding to a first processing station 4U of the processing station 4 to be described below and a position corresponding to a second processing station 4L thereof.

The processing station 4 is equipped with the first processing station 4U and the second processing station 4L. The first processing station 4U and the second processing station 4L are spatially separated from each other by a partition wall or a shutter, and are arranged in a height direction.

The first processing station 4U and the second processing station 4L have the same configuration. As illustrated in FIG. 1, each of the first and second processing stations 4U and 4L is equipped with a transfer section 16, a second transfer device 17, a plurality of first processing units (CH1) 18, and a plurality of second processing units (CH2) 19.

The second transfer device 17 is provided inside the transfer section 16, and transfers the wafer W among the delivery station 3, the first processing units 18, and the second processing units 19.

The second transfer device 17 is equipped with a single wafer holder configured to hold a single sheet of wafer W. The second transfer device 17 is configured to be movable horizontally and vertically and pivotable around a vertical axis and to transfer the single sheet of wafer W by using the wafer holder.

The plurality of first processing units 18 and the plurality of second processing units 19 are arranged adjacent to the transfer section 16. As an example, the plurality of first processing units 18 is arranged at the positive Y-axis side of the transfer section 16 along the X-axis direction, whereas the plurality of second processing units 19 is arranged at the negative Y-axis side of the transfer section 16 along the X-axis direction.

Each first processing unit 18 is configured to perform a predetermined processing on the wafer W whose main surface Wa (see FIG. 3) faces upwards. In the exemplary embodiment, the first processing unit 18 performs a processing of etching a film F (see FIG. 3) formed on a rear surface Wb (see FIG. 3) of the wafer W.

Here, the main surface Wa of the wafer W refers to a surface on which a pattern (a circuit formed to have a protruding shape) is formed, and the rear surface Wb refers to a surface opposite to the main surface Wa. Details of the first processing unit 18 will be described later.

The film F formed on the rear surface Wb of the wafer W is a silicon nitride film, a silicon oxide film, or a multilayer film including a silicon nitride film and a silicon oxide film. In the present exemplary embodiment, the film F is a multilayer film in which a silicon oxide film F1 (see FIG. 3) and a silicon nitride film F2 (see FIG. 3) are stacked in order from the rear surface Wb of the wafer W.

Each second processing unit 19 is configured to perform a predetermined processing on the wafer W whose rear surface Wb (see FIG. 3) faces upwards. In the exemplary embodiment, the second processing unit 19 mainly performs a processing of polishing the rear surface Wb of the wafer W (see FIG. 3) and cleaning the rear surface Wb of the wafer W (see FIG. 3) with a brush. Details of the second processing unit 19 will be described later.

Further, as illustrated in FIG. 1, the substrate processing system 1 is equipped with a control device 5. The control device 5 is, for example, a computer, and includes a controller 6 and a storage unit 7. The storage unit 7 stores therein a program for controlling various kinds of processings performed in the substrate processing system 1. The controller 6 controls an operation of the substrate processing system 1 by reading and executing the program stored in the storage unit 7.

The program is recorded on a computer-readable recording medium and may be installed from this recording medium to the storage unit 7 of the control device 5. The computer-readable recording medium may be, for example, a hard disk (HD), a flexible disk (FD), a compact disk (CD), a magneto-optical disk (MO), a memory card, or the like.

In the substrate processing system 1 configured as described above, the first transfer device 13 of the carry-in/out station 2 takes out a wafer W from the cassette and places the wafer W on the substrate placing unit 14 of the delivery station 3. The wafer W placed on the substrate placing unit 14 is taken out from the substrate placing unit 14 and carried into the first processing unit 18 by the second transfer device 17 of the processing station 4. Then, the first processing unit 18 performs an etching processing on the wafer W. When the etching processing is ended, the second transfer device 17 takes out the processed wafer W from the first processing unit 18 and transfers the wafer W to the inverting mechanism 15. Then, the inverting mechanism 15 inverts the wafer W. The inverted wafer W is taken out from the inverting mechanism 15 and carried into the second processing unit 19 by the second transfer device 17. Then, the second processing unit 19 performs a polishing processing and a cleaning processing on the wafer W. When the polishing processing and the cleaning processing are ended, the second transfer device 17 takes out the processed wafer W from the second processing unit 19 and transfers the wafer W to the inverting mechanism 15. Then, the inverting mechanism 15 inverts the wafer W again. The inverted wafer W is taken out from the inverting mechanism 15 and returned back to the cassette C by the first transfer device 13.

### <Substrate Processing>

FIG. 3 shows a configuration of the wafer W according to the exemplary embodiment. The wafer W illustrated in FIG. 3 is, for example, a silicon wafer, and a pattern is formed on the main surface Wa and the multilayer film F in which the silicon oxide film F1 and the silicon nitride film F2 are stacked is formed on the rear surface Wb opposite to the main surface Wa. Also, FIG. 2 omits illustration of the pattern formed on the main surface Wa of the wafer W for the convenience of description.

A foreign substance caused by the contact between the rear surface Wb and the substrate holder exists on the rear surface Wb of the wafer W. The foreign substance is, for example, a particle P1 adhering to the rear surface Wb of the wafer W, a burr B1 generated on the rear surface Wb of the wafer W, and a particle P2 buried in the film F. The substrate processing system removes the foreign substance from the rear surface Wb of the wafer W by performing, for example, a polishing processing or a cleaning processing with a brush (hereinafter, appropriately referred to as “polishing processing or the like”).

Meanwhile, when the polishing processing is performed on the rear surface Wb of the wafer W, the rear surface Wb of the wafer W may be damaged by the particle P1 adhering to the rear surface Wb of the wafer W or the particle P2 buried in the film F, which may cause generation of a new burr B1. Also, when the cleaning processing is performed on the rear surface Wb of the wafer W, it is difficult to remove the particle P2 buried in the film F.

Thus, the substrate processing system 1 according to the exemplary embodiment is configured to etch the film F formed on the rear surface Wb in the first processing unit 18 to remove the particles P1 and P2 before the polishing processing or the like is performed in the second processing unit 19, and configured to perform the polishing processing or the like to remove the burr B1 remaining on the rear surface Wb. Accordingly, it is possible to appropriately remove the foreign substance from the rear surface Wb of the wafer W on which the film F has been formed.

### <Configuration of First Processing Unit>

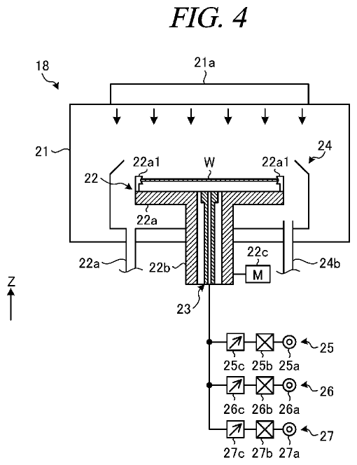

Hereinafter, a configuration of the first processing unit 18 according to the exemplary embodiment will be described with reference to FIG. 4. FIG. 4 is a diagram schematically illustrating the first processing unit 18 according to the exemplary embodiment. As illustrated in FIG. 4, the first processing unit 18 is equipped with a chamber 21, a substrate holder 22, a processing liquid supply 23, and a recovery cup 24.

The chamber 21 accommodates the substrate holder 22, the processing liquid supply 23, and the recovery cup 24. An FFU (Fan Filter Unit) 21a is provided on a ceiling of the chamber 21. The FFU 21a is configured to form a downflow in the chamber 21.

The substrate holder 22 is equipped with a holder 22a configured to horizontally hold the wafer W, a column member 22b extending in a vertical direction and configured to support the holder 22a, and a driver 22c configured to rotate the column member 22b around a vertical axis.

A plurality of grippers 22a1 configured to grip a peripheral portion of the wafer W is provided on an upper surface of the holder 22a. The wafer W is horizontally held by the grippers 22a1 while it is slightly spaced from the upper surface of the holder 22a.

The processing liquid supply 23 is inserted through a hollow portion which is formed through the holder 22a and the column member 22b along a rotation axis. A flow path extending along the rotation axis is formed within the processing liquid supply 23.

A first chemical liquid supply 25, a second chemical liquid supply 26, and a rinse liquid supply 27 are connected in parallel to the flow path formed within the processing liquid supply 23.

The first chemical liquid supply 25 has a first chemical liquid source 25a, a valve 25b, and a flow rate controller 25c in this order from an upstream side. The first chemical liquid source 25a is, for example, a tank that stores a first chemical liquid. The flow rate controller 25c adjusts a flow rate of the first chemical liquid which is supplied to the processing liquid supply 23 from the first chemical liquid source 25a via the valve 25b. In the present exemplary embodiment, the first chemical liquid is hydrofluoric acid.

The second chemical liquid supply 26 has a second chemical liquid source 26a, a valve 26b, and a flow rate controller 26c in this order from an upstream side. The second chemical liquid source 26a is, for example, a tank that stores a second chemical liquid. The flow rate controller 26c adjusts a flow rate of the second chemical liquid which is supplied to the processing liquid supply 23 from the second chemical liquid source 26a via the valve 26b. In the present exemplary embodiment, the second chemical liquid is SC-1 (a mixture of ammonia, a hydrogen peroxide, and water).

The rinse liquid supply 27 has a rinse liquid source 27a, a valve 27b, and a flow rate controller 27c in this order from an upstream side. The rinse liquid source 27a is, for example, a tank that stores a rinse liquid, such as DIW or the like. The flow rate controller 27c adjusts a flow rate of the rinse liquid which is supplied to the processing liquid supply 23 from the rinse liquid source 27a via the valve 27b.

The processing liquid supply 23 supplies the rear surface Wb of the wafer W (see FIG. 3) held by the substrate holder 22 with the chemical liquid supplied from at least one of the first chemical liquid supply 25, the second chemical liquid supply 26, and the rinse liquid supply 27.

Further, the first processing unit 18 may heat the chemical liquid discharged from the processing liquid supply 23 to a predetermined temperature with a non-illustrated heater.

The recovery cup 24 is provided to surround the substrate holder 22. A drain port 24a through which the chemical liquid supplied from the processing liquid supply 23 is drained to the outside of the chamber 21 and an exhaust port 24b through which an atmosphere within the chamber 31 is exhausted are formed at a bottom portion of the recovery cup 24.

The first processing unit 18 is configured as described above, and holds the peripheral portion of the wafer W whose main surface Wa faces upwards with the plurality of grippers 22a1 and then rotates the wafer W by using the driver 22c.

Then, the first processing unit 18 sequentially supplies the chemical liquids from the processing liquid supply 23 toward a central portion of the rear surface Wb of the wafer W being rotated. In the present exemplary embodiment, the first processing unit 18 supplies hydrofluoric acid, DIW, SC-1, and DIW in this order from the processing liquid supply 23 toward the central portion of the rear surface Wb of the wafer W being rotated.

As a result, the film F formed on the rear surface Wb of the wafer W is etched. At this time, the particle P1 adhering to the rear surface Wb of the wafer W and the particle P2 buried in the film F on the rear surface Wb of the wafer W are removed.

The first processing unit 18 performs a rinsing processing of washing away SC-1 remaining on the wafer W with DIW, which is the rinse liquid, and then performs a drying processing of drying the wafer W by rotating the wafer W.

### <Configuration of Second Processing Unit>

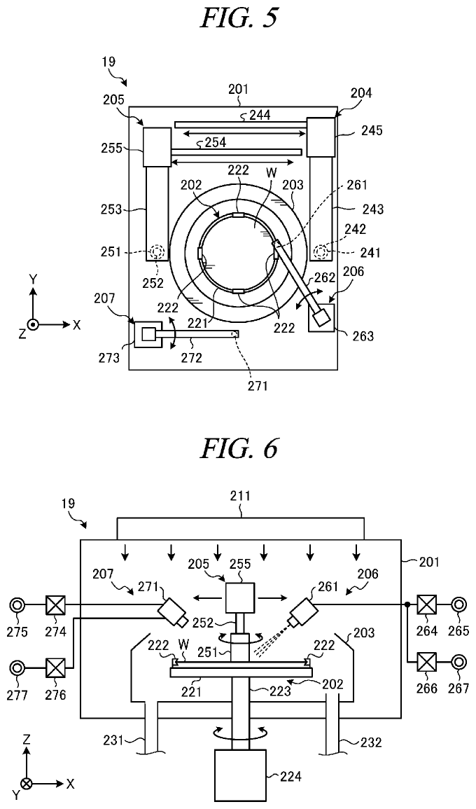

Hereinafter, a configuration of the second processing unit 19 according to the exemplary embodiment will be described with reference to FIG. 5 and FIG. 6. FIG. 5 is a plan view schematically illustrating the second processing unit 19 according to the exemplary embodiment. FIG. 6 is a side view schematically illustrating the second processing unit 19 according to the exemplary embodiment.

As illustrated in FIG. 5 and FIG. 6, the second processing unit 19 is equipped with a chamber 201, a substrate holder 202, a recovery cup 203, a polishing mechanism 204, a cleaning mechanism 205, a first supply 206, and a second supply 207.

The chamber 201 accommodates the substrate holder 202, the recovery cup 203, the polishing mechanism 204, the cleaning mechanism 205, the first supply 206, and the second supply 207. An FFU (Fan Filter Unit) 211 is provided on a ceiling of the chamber 201. The FFU 211 is configured to form a downflow in the chamber 201.

The substrate holder 202 is equipped with a main body 221 having a greater diameter than the wafer W, a plurality of grippers 222 provided on an upper surface of the main body 221, a column member 223 configured to support the main body 221, and a driver 224 configured to rotate the column member 223.

The substrate holder 202 holds the wafer W thereon by gripping a peripheral portion of the wafer with the plurality of grippers 222. Accordingly, the wafer W is horizontally held while it is slightly spaced from the upper surface of the main body 221.

The recovery cup 203 is provided to surround the substrate holder 202. A drain port 231 through which chemical liquids discharged from the first supply 206 and the second supply 207 are drained to the outside of the chamber 201 and an exhaust port 232 through which an atmosphere within the chamber 201 is exhausted are formed at a bottom portion of the recovery cup 203.

The polishing mechanism 204 is equipped with a polishing brush 241 and an arm 243 extending in the horizontal direction (here, in the Y-axis direction) and configured to support the polishing brush 241 from above via a shaft 242. The polishing mechanism 204 is also equipped with a moving mechanism 245 configured to move the arm 243 in the horizontal direction (here, in the X-axis direction) along a rail 244. The moving mechanism 245 can also move the arm 243 in the vertical direction (Z-axis direction). Further, the polishing mechanism 204 is equipped with a non-illustrated rotating mechanism, and may use the rotating mechanism to rotate the polishing brush 241 around the shaft 242.

The cleaning mechanism 205 is equipped with a brush 251 and an arm 253 extending in the horizontal direction (here, in the Y-axis direction) and configured to support the brush 251 from above via a shaft 252. The cleaning mechanism 205 is also equipped with a moving mechanism 255 configured to move the arm 253 in the horizontal direction (here, in the X-axis direction) along a rail 254. The moving mechanism 255 can also move the arm 253 in the vertical direction (Z-axis direction). Further, the cleaning mechanism 205 is equipped with a non-illustrated rotating mechanism, and may use the rotating mechanism to rotate the brush 251 around the shaft 252.

The first supply 206 is disposed outside the recovery cup 203. The first supply 206 is equipped with a nozzle 261, an arm 262 extending in the horizontal direction and configured to support the nozzle 261, and a rotating/elevating mechanism 263 configured to rotate and vertically move the arm 262.

The nozzle 261 is connected to a first cleaning liquid source 265 via a valve 264, a flow rate controller (not shown), and the like. Also, the nozzle 261 is connected to a rinse source 267 via a valve 266, a flow rate controller (not shown), and the like. The first supply 206 is configured to discharge a first cleaning liquid supplied from the first cleaning liquid source 265 toward the wafer W. Also, the first supply 206 is configured to discharge a rinse liquid supplied from the rinse liquid source 267 toward the wafer W. The first cleaning liquid supplied from the first cleaning liquid source 265 is, for example, SC-1. Also, the rinse liquid supplied from the rinse liquid source 267 is, for example, DIW.

The second supply 207 is disposed outside the recovery cup 203. The second supply 207 is equipped with a nozzle 271, an arm 272 extending in the horizontal direction and configured to support the nozzle 271, and a rotating/elevating mechanism 273 configured to rotate and vertically move the arm 272.

The nozzle 271 is, for example, a dual-fluid nozzle, and is connected to a second cleaning liquid source 275 via a valve 274, a flow rate controller (not shown), and the like. The nozzle 271 is also connected to a gas source 277 via a valve 276, a flow rate controller (not shown), and the like.

The second supply 207 is configured to supply a cleaning liquid in the form of mist, which is obtained by mixing the cleaning liquid supplied from the second cleaning liquid source 275 and the gas supplied from the gas source 277 in the nozzle 271, to the wafer W from the nozzle 271. The cleaning liquid supplied from the second cleaning liquid source 275 is, for example, DIW, and the gas supplied from the gas source 277 is an inert gas, such as nitrogen or the like.

The second processing unit 19 is configured as described above, and holds the peripheral portion of the wafer W whose rear surface Wb faces upwards with the substrate holder 202 and then rotates the wafer W. Thereafter, the second processing unit 19 brings the polishing brush 241 of the polishing mechanism 204 disposed above the wafer W being rotated into contact with the rear surface Wb of the wafer W. Then, the second processing unit 19 polishes the rear surface Wb of the wafer W by moving the polishing brush 241, for example, from the central portion to the outer peripheral portion of the wafer W while rotating the polishing brush 241. Thus, the burr B1 remaining on the rear surface Wb of the wafer W after the etching processing in the first processing unit 18 is removed. In this process, a residue of the burr B1 remains on the rear surface Wb of the wafer W.

Subsequent to the polishing processing on the rear surface Wb of the wafer W, the second processing unit 19 brings the brush 251 of the cleaning mechanism 205 into contact with the wafer W while supplying the first cleaning liquid from the first supply 206 toward the rear surface Wb of the wafer W being rotated. Then, the second processing unit 19 moves the brush 251, for example, from the central portion to the outer peripheral portion of the wafer W while rotating the brush 251. Thus, the rear surface Wb of the wafer W is cleaned to remove the residue of the burr B1 remaining on the rear surface Wb of the wafer W.

Then, the second processing unit 19 places the nozzle 271 of the second supply 207 to above the wafer W being rotated, and supplies a second cleaning liquid in the form of mist toward the rear surface Wb of the wafer W from the nozzle 271. Thus, the rear surface Wb of the wafer W is cleaned to remove foreign substances, which have not been removed by the etching processing in the first processing unit 18, the polishing processing in the second processing unit 19, and the cleaning processing with the brush 251, from the rear surface Wb.

Thereafter, the second processing unit 19 performs a rinsing processing of washing away the chemical liquid remaining on the wafer W by supplying the rinse liquid from the first supply 206. Also, the second processing unit 19 performs a drying processing of drying the wafer W by rotating the wafer W.

### <Specific Operation of Substrate Processing System>

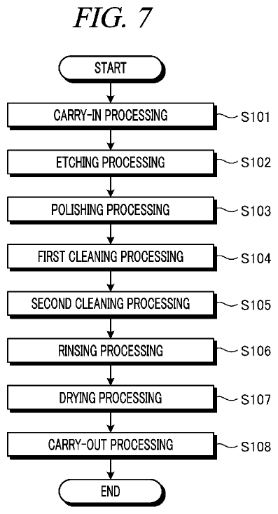

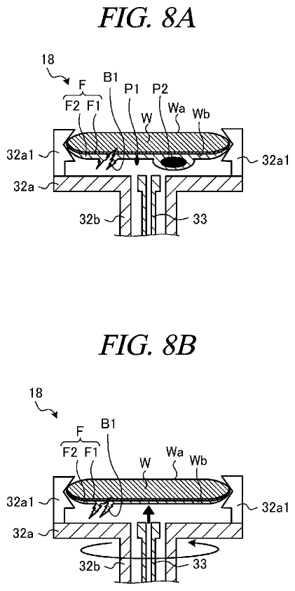

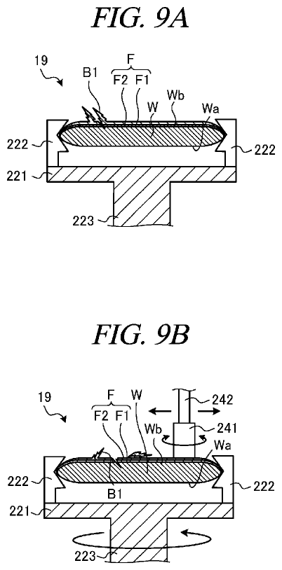

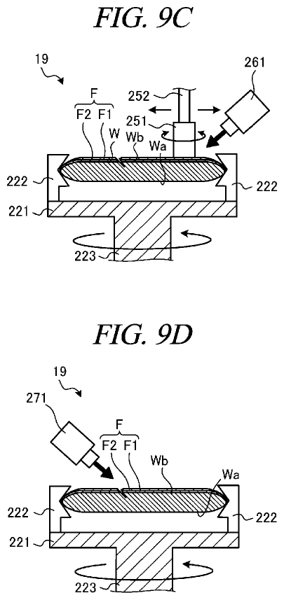

Now, a specific operation of the substrate processing system 1 according to the exemplary embodiment will be described. FIG. 7 is a flowchart illustrating a sequence of substrate processings performed by the substrate processing system 1 according to the exemplary embodiment. Also, FIG. 8A and FIG. 8B are diagrams illustrating examples of operations of the first processing unit 18, and FIG. 9A to FIG. 9D are diagrams illustrating examples of operations of the second processing unit 19. More specifically, FIG. 8A and FIG. 8B show examples of operations of an etching processing (process S102) shown in FIG. 7. Also, FIG. 9A and FIG. 9B show examples of operations of a polishing processing (process S103) shown in FIG. 7. FIG. 9C shows an example of an operation of a first cleaning processing (process S104) shown in FIG. 7, and FIG. 9D shows an example of an operation of a second cleaning processing (process S105) shown in FIG. 7. The processing sequence illustrated in FIG. 7 is performed under control of the control device 5.

In the substrate processing system 1 according to the exemplary embodiment, the etching processing (process S102) shown in FIG. 7 is performed by the first processing unit 18. Also, in the substrate processing system 1, the polishing processing (process S103) to a drying processing (process S107) shown in FIG. 7 are performed by the second processing unit 19.

As illustrated in FIG. 7, a carry-in processing is first performed in the substrate processing system 1 (process S101). Specifically, the wafer W is carried into the chamber 21 of the first processing unit 18 by the second transfer device 17. In this case, the wafer W whose main surface Wa of the wafer W faces upwards is carried into the chamber 21.

Then, the etching processing is performed in the first processing unit 18 (process S102). Specifically, the controller 6 operates the substrate holder 22 to hold the wafer W with the plurality of grippers 22a1 of the holder 22a. In this process, the foreign substances, such as the particles P1 and P2 and the burr B1, exist on the rear surface Wb of the wafer W on which the film F has been formed, as illustrated in FIG. 8A.

Thereafter, the controller 6 operates the driver 22c to rotate the wafer W, as illustrated in FIG. 8B.

Then, the controller 6 operates the processing liquid supply 23 to supply hydrofluoric acid toward the rear surface Wb of the wafer W being rotated. For example, the controller 6 supplies the hydrofluoric acid with a concentration of 49% and a temperature of 20° C. to 50° C. for 10 seconds to 180 seconds.

Subsequently, the controller 6 operates the processing liquid supply 23 to supply DIW toward the rear surface Wb of the wafer W being rotated.

Then, the controller 6 operates the processing liquid supply 23 to supply SC-1 toward the rear surface Wb of the wafer W being rotated. For example, the controller 6 supplies the SC-1 with a mixing ratio of ammonia:hydrogen peroxide:water=1:1:5 to 1:10:100 and a temperature of 20° C. to 70° C. for 10 seconds to 30 seconds.

Thereafter, the controller 6 operates the processing liquid supply 23 to supply DIW toward the rear surface Wb of the wafer W.

Subsequently, the controller 6 scatters the chemical liquid remaining on the rear surface Wb of the wafer W to dry the wafer W by increasing, for example, the rotation number of the wafer W.

Accordingly, as illustrated in FIG. 8B, the film F is etched such that the film F is left on the rear surface Wb of the wafer W by the chemical liquids (here, hydrofluoric acid and SC-1) sequentially supplied thereto. In this case, the particle P1 adhering to the rear surface Wb of the wafer W and the particle P2 buried in the film F on the rear surface Wb of the wafer W are removed together with the film F.

As described above, the first processing unit 18 etches the film F in the etching processing such that the film F is left on the rear surface Wb of the wafer W. Accordingly, it is possible to suppress damage to the rear surface Wb of the wafer W in the polishing processing subsequent to the etching processing.

Also, in the etching processing, the first processing unit 18 etches the film F by sequentially supplying the chemical liquids to the rear surface Wb of the wafer W. Accordingly, the silicon nitride film F2, which is the surface layer of the film F, can be selectively etched.

Then, in the substrate processing system 1, a substrate inverting processing is performed. Specifically, the second transfer device 17 carries out the wafer W from the chamber 21, and after the wafer W is inverted by the inverting mechanism 15, the second transfer device 17 carries the wafer W into the chamber 201 of the second processing unit 19. In this case, the wafer W whose rear surface Wb faces upwards, i.e., whose main surface Wa faces downwards is carried into the chamber 201.

Thereafter, in the second processing unit 19, the polishing processing is performed (process S103). Specifically, the controller 6 operates the substrate holder 202 to hold the wafer W with the plurality of grippers 222 of the substrate holder 202. In this process, the foreign substances, such as the burr B1, remains on the rear surface Wb of the wafer W, as illustrated in FIG. 9A.

Subsequently, the controller 6 operates the driver 22c to rotate the wafer W, as illustrated in FIG. 9B.

Then, the controller 6 operates the polishing mechanism 204 to bring the polishing brush 241, which is disposed above the wafer W being rotated, into contact with the rear surface Wb of the wafer W. Also, the controller 6 polishes the rear surface Wb of the wafer W by moving the polishing brush 241, for example, from the central portion to the outer peripheral portion of the wafer W while rotating the polishing brush 241.

Thus, the burr B1 remaining on the rear surface Wb of the wafer W is removed, as illustrated in FIG. 9C. In this process, the residue of the burr B1 remains on the rear surface Wb of the wafer W.

Thereafter, in the second processing unit 19, the first cleaning processing is performed (process S104). Specifically, the controller 6 operates the cleaning mechanism 205 to bring the brush 251, which is disposed above the wafer W being rotated, into contact with the rear surface Wb of the wafer W. Also, the controller 6 operates the first supply 206 to supply SC-1, which is the first cleaning liquid, toward the rear surface Wb of the wafer W from the nozzle 261 disposed above the wafer W being rotated. For example, the controller 6 supplies the SC-1 with the mixing ratio of ammonia:hydrogen peroxide:water=1:1:5 to 1:10:100 and the temperature of 20° C. to 70° C. Then, the controller 6 cleans the rear surface Wb of the wafer W by moving the brush 251, for example, from the central portion to the outer peripheral portion of the wafer W while rotating the brush 251.

Accordingly, as illustrated in FIG. 9C, the residue of the burr B1 remaining on the rear surface Wb of the wafer W is removed.

Then, in the second processing unit 19, the second cleaning processing is performed (process S105). Specifically, the controller 6 operates the second supply 207 to supply the second cleaning liquid in the form of mist toward the rear surface Wb of the wafer W from the nozzle 271 disposed above the wafer W being rotated, as illustrated in FIG. 9D. Thus, the rear surface Wb of the wafer W is cleaned to remove the foreign substances, which have not been removed by the etching processing (process S102), the polishing processing (process S103), and the first cleaning processing (process S104), from the rear surface Wb.

Thereafter, in the second processing unit 19, the rinsing processing is performed (process S106). Specifically, the controller 6 operates the first supply 206 to supply a rinse liquid toward the rear surface Wb of the wafer W from the nozzle 261 disposed above the wafer W being rotated. Thus, the chemical liquid on the rear surface Wb of the wafer W is washed away.

Subsequently, in the second processing unit 19, the drying processing is performed (process S107). Specifically, the controller 6 scatters the chemical liquid remaining on the rear surface Wb of the wafer W to dry the wafer W by increasing, for example, the rotation number of the wafer W.

Then, in the substrate processing system 1, a carry-out processing is performed (process S108). Specifically, the wafer W is carried out from the chamber 201 by the second transfer device 17 and then inverted again by the inverting mechanism 15. After the wafer W is inverted again by the inverting mechanism 15, the wafer W is taken out from the inverting mechanism 15 by the first transfer device 13 and then accommodated in the cassette C. In this case, the wafer W whose main surface Wa faces upwards is accommodated in the cassette C. When the carry-out processing is ended, a substrate processing is ended.

In the above-described exemplary embodiment, it has been described that the first cleaning processing is performed after the polishing processing. However, the first cleaning processing may be performed after the etching processing and before the polishing processing. Also, the first cleaning processing and the second cleaning processing may be performed after the etching processing and before the polishing processing. Alternatively, the first cleaning processing and the second cleaning processing may be omitted.

### <Improvement of Particle Removal Rate by Substrate Processing Method According to Exemplary Embodiment>

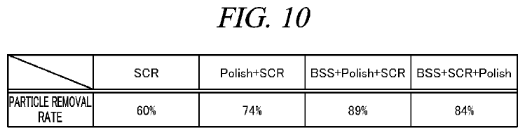

FIG. 10 is a diagram for describing an improvement of a particle removal rate by a substrate processing method according to the exemplary embodiment. The present inventors have processed the wafer W by the substrate processing method according to the exemplary embodiment and examined the particle removal rate on the rear surface Wb of the wafer W.

In FIG. 10, “SCR” indicates a result of sequentially performing the first cleaning processing and the second cleaning processing without performing the etching processing and the polishing processing (Comparative Example 1). In FIG. 10, “Polish+SCR” indicates a result of sequentially performing the polishing processing, the first cleaning processing, and the second cleaning processing without performing the etching processing (Comparative Example 2). In FIG. 10, “BSS+Polish+SCR” indicates a result of sequentially performing the etching processing, the polishing processing, the first cleaning processing, and the second cleaning processing as in the substrate processing method according to the exemplary embodiment (Example 1). In FIG. 10, “BSS+SCR+Polish” indicates a result of inserting the order of the polishing processing, and the first cleaning processing and the second cleaning processing as in Example 1 (Example 2).

In Comparative Examples 1 and 2 in which no etching processing is performed, the particle removal rate is less than 80% and do not satisfy a predetermined allowable specification, whereas in Examples 1 and 2 in which the etching processing is performed prior to the polishing processing, the first cleaning processing, and the second cleaning processing, the particle removal rate is 80% or more and satisfies the predetermined allowable specification. According to the result of comparison, it can be seen that the foreign substance is appropriately removed from the rear surface Wb of the wafer W by the substrate processing method according to the exemplary embodiment.

As described above, the foreign substance can be appropriately removed from the rear surface Wb of the wafer W on which the film F has been formed by the substrate processing method according to the exemplary embodiment, as compared with the method in which no etching processing is performed.

### Modification Example

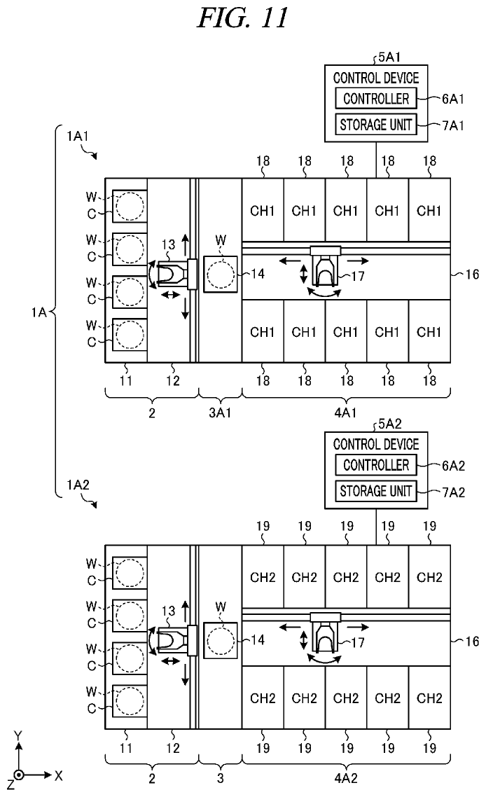

The configuration of the substrate processing system is not limited to that shown in the exemplary embodiment. Thus, hereinafter, the configuration of the substrate processing system according to a modification example of the exemplary embodiment will be described with reference to FIG. 11. FIG. 11 is a plan view schematically illustrating a substrate processing system 1A according to the modification example of the exemplary embodiment.

A substrate processing system 1A according to the modification example illustrated in FIG. 11 includes a first substrate processing system 1A1 configured to perform the etching processing and a second substrate processing system 1A2 configured to perform the polishing processing, the first cleaning processing, and the second cleaning processing.

The first substrate processing system 1A1 is equipped with the carry-in/out station 2, a delivery station 3A1, and a processing station 4A1. The carry-in/out station 2 is the same as the carry-in/out station 2 of the substrate processing system 1 according to the exemplary embodiment, and, thus, description thereof will be omitted.

The plurality of substrate placing units 14 is provided inside the delivery station 3A1. However, unlike the delivery station 3 of the substrate processing system 1 according to the exemplary embodiment, the delivery station 3A1 is not provided therein with the inverting mechanism 15.

Like the processing station 4 of the substrate processing system 1 according to the exemplary embodiment, the processing station 4A1 is equipped with the first processing station 4U and the second processing station 4L. The first processing station 4U and the second processing station 4L have the same configuration, and are equipped with the transfer section 16, the second transfer device 17, and the plurality of first processing units (CH1) 18. Unlike the first processing station 4U and the second processing station 4L of the substrate processing system 1 according to the exemplary embodiment, the first processing station 4U and the second processing station 4L are not equipped with the plurality of second processing units (CH2) 19.

The second substrate processing system 1A2 is equipped with the carry-in/out station 2, the delivery station 3, and a processing station 4A2. The carry-in/out station 2 and the delivery station 3 are the same as the carry-in/out station 2 and the delivery station 3, respectively, of the substrate processing system 1 according to the exemplary embodiment, and, thus, description thereof will be omitted.

Like the processing station 4 of the substrate processing system 1 according to the exemplary embodiment, the processing station 4A2 is equipped with the first processing station 4U and the second processing station 4L. The first processing station 4U and the second processing station 4L have the same configuration, and are equipped with the transfer section 16, the second transfer device 17, and the plurality of second processing units (CH2) 19. Unlike the first processing station 4U and the second processing station 4L of the substrate processing system 1 according to the exemplary embodiment, the first processing station 4U and the second processing station 4L are not equipped with the plurality of first processing units (CH1) 18.

The first substrate processing system 1A1 is also equipped with a control device 5A1, as illustrated in FIG. 11. The control device 5A1 is, for example, a computer, and includes a controller 6A1 and a storage unit 7A1. The storage unit 7A1 stores therein a program for controlling various kinds of processings performed in the first substrate processing system 1A1. The controller 6A1 controls an operation of the first substrate processing system 1A1 by reading and executing the program stored in the storage unit 7A1.

The second substrate processing system 1A2 is also equipped with a control device 5A2, as illustrated in FIG. 11. The control device 5A2 is, for example, a computer, and includes a controller 6A2 and a storage unit 7A2. The storage unit 7A2 stores therein a program for controlling various kinds of processings performed in the second substrate processing system 1A2. The controller 6A2 controls an operation of the second substrate processing system 1A2 by reading and executing the program stored in the storage unit 7A2.

These programs are recorded on a computer-readable recording medium and may be installed from this recording medium to the storage unit 7A1 of the control device 5A1 or the storage unit 7A2 of the control device 5A2. The computer-readable recording medium may be, for example, a hard disk (HD), a flexible disk (FD), a compact disk (CD), a magneto-optical disk (MO), a memory card, or the like.

In the substrate processing system 1A configured as described above, the first transfer device 13 of the first substrate processing system 1A1 takes out a wafer W from the cassette and places the wafer W on the substrate placing unit 14 of the delivery station 3A1. The wafer W placed on the substrate placing unit 14 is taken out from the substrate placing unit 14 and carried into the first processing unit 18 by the second transfer device 17 of the processing station 4A1. Then, the first processing unit 18 performs the etching processing on the wafer W. When the etching processing is ended, the second transfer device 17 takes out the processed wafer W from the first processing unit 18 and places the wafer W on the substrate placing unit 14 of the delivery station 3A1. The wafer W placed on the substrate placing unit 14 is taken out from the substrate placing unit 14 and returned back to the cassette C by the first transfer device 13. The wafer W returned back to the cassette C is transferred from the first substrate processing system 1A1 to the cassette placing section 11 of the second substrate processing system 1A2.

Thereafter, the wafer W is taken out from the cassette C and transferred to the inverting mechanism 15 of the delivery station 3 by the first transfer device 13 of the second substrate processing system 1A2. Then, the inverting mechanism 15 inverts the wafer W. The inverted wafer W is taken out from the inverting mechanism 15 and carried into the second processing unit 19 by the second transfer device 17. Then, the second processing unit 19 performs the polishing processing and the cleaning processing on the wafer W. When the polishing processing and the cleaning processing are ended, the second transfer device 17 takes out the processed wafer W from the second processing unit 19 and transfers the wafer W to the inverting mechanism 15. Then, the inverting mechanism 15 inverts the wafer W again. The inverted wafer W is taken out from the inverting mechanism 15 and returned back to the cassette C by the first transfer device 13.

### Effects

A substrate processing method according to the exemplary embodiment includes etching (for example, process S102) a film formed on a rear surface of a substrate opposite to a main surface of the substrate; and polishing (for example, process S103) the rear surface of the substrate after the etching of the film. In the etching of the film, a film (for example, film F) formed on a rear surface (for example, rear surface Wb) of a substrate (for example, wafer W) opposite to a main surface (for example, main surface Wa) of the substrate is etched. In the polishing of the rear surface, the rear surface of the substrate is polished after the etching of the film. Therefore, it is possible to appropriately remove the foreign substance from the rear surface of the substrate on which the film has been formed.

The substrate processing method according to the exemplary embodiment may further include cleaning (for example, process S104) the rear surface of the substrate with a brush (for example, brush 251) after the polishing of the rear surface, or after the etching of the film and before the polishing of the rear surface. Therefore, it is possible to remove the residue of the burr (for example, the burr B1) remaining on the rear surface of the substrate or the particle (for example, the particle P1) adhering to the rear surface of the substrate.

In the substrate processing method according to the exemplary embodiment, in the cleaning of the rear surface of the substrate with the brush, the rear surface of the substrate may be cleaned with the brush while a cleaning liquid (for example, first cleaning liquid) is supplied to the rear surface of the substrate. Therefore, it is possible to more appropriately remove the residue of the burr remaining on the rear surface of the substrate, or the particle adhering to the rear surface of the substrate.

The substrate processing method according to the exemplary embodiment may further include cleaning (for example, process S105) the rear surface of the substrate by supplying a cleaning liquid (for example, second cleaning liquid) in a form of mist to the rear surface of the substrate after the cleaning of the rear surface of the substrate with the brush. Therefore, it is possible to remove the foreign substance, which has not been removed by the cleaning of the rear surface of the substrate with the brush, from the rear surface of the substrate.

In the substrate processing method according to the exemplary embodiment, in the etching of the film, the film may be etched such that the film is left on the rear surface of the substrate. Therefore, it is possible to suppress the damage to the rear surface of the substrate in the polishing of the rear surface subsequent to the etching of the film.

In the substrate processing method according to the exemplary embodiment, in the etching of the film, the film may be etched by sequentially supplying multiple chemical liquids (for example, hydrofluoric acid and SC-1) to the rear surface of the substrate. Therefore, it is possible to selectively etch the surface layer (for example, silicon nitride film) of the film (for example, multilayer film including silicon nitride film and silicon oxide film) formed on the rear surface of the substrate.

In the substrate processing method according to the exemplary embodiment, the film may be a silicon nitride film, a silicon oxide film, or a multilayer film including a silicon nitride film and a silicon oxide film. Therefore, it is possible to appropriately remove the foreign substance from the rear surface of the substrate on which the silicon nitride film, the silicon oxide film or the multilayer film including the silicon nitride film and the silicon oxide film has been formed.

A substrate processing system (for example, substrate processing system 1 (1A)) includes an etching apparatus (for example, first processing unit 18); and a rear surface processing apparatus (for example, second processing unit 19). The etching apparatus is configured to etch a film formed on a rear surface of a substrate opposite to a main surface of the substrate. The rear surface processing apparatus includes a polishing mechanism (for example, polishing mechanism 204) configured to polish the rear surface of the substrate after the film is etched. Therefore, it is possible to appropriately remove the foreign substance from the rear surface of the substrate on which the film has been formed.

The substrate processing system according to the exemplary embodiment may further include an inverting mechanism (for example, inverting mechanism 15). The etching apparatus may etch the film while the main surface of the substrate faces upwards. The polishing mechanism may polish, after the film is etched, the rear surface of the substrate inverted by the inverting mechanism. The inverting mechanism may invert the substrate again after the rear surface of the substrate is polished by the polishing mechanism. Therefore, it is possible to finish the substrate processing on the substrate whose main surface faces upwards.

In the substrate processing system according to the exemplary embodiment, the rear surface processing apparatus may further include a cleaning mechanism (for example, cleaning mechanism 205) configured to clean, with a brush, the rear surface of the substrate after the rear surface of the substrate is polished by the polishing mechanism, or the rear surface of the substrate after the film is etched by the etching apparatus and before the rear surface of the substrate is polished by the polishing mechanism. Therefore, it is possible to more appropriately remove the residue of the burr remaining on the rear surface of the substrate or the particle adhering to the rear surface of the substrate.

The substrate processing system according to the exemplary embodiment may further include an inverting mechanism (for example, inverting mechanism 15). The etching apparatus may etch the film while the main surface of the substrate faces upwards. The polishing mechanism may polish, after the film is etched, the rear surface of the substrate inverted by the inverting mechanism. The cleaning mechanism may clean the rear surface of the substrate after the rear surface of the substrate is polished by the polishing mechanism. The inverting mechanism may invert the substrate again after the rear surface of the substrate is cleaned by the cleaning mechanism. Therefore, it is possible to finish the substrate processing on the substrate whose main surface faces upwards.

Herein, it should be noted that the above-described exemplary embodiments are illustrative in all aspects and are not anyway limiting. Further, the above-described exemplary embodiments may be omitted, replaced and modified in various ways without departing from the scope and the spirit of claims.

### EXPLANATION OF CODES

1, 1A: Substrate processing system
15: Inverting mechanism
18: First processing unit
19: Second processing unit
23: Processing liquid supply
204: Polishing mechanism
205: Cleaning mechanism
206: First supply
207: Second supply
241: Polishing brush
251: Brush
F: Film
W: Wafer
Wa: Main surface
Wb: Rear surface

1. A substrate processing method, comprising:
etching a film formed on a rear surface of a substrate opposite to a main surface of the substrate; and
polishing the rear surface of the substrate after the etching of the film.

2. The substrate processing method of claim 1, further comprising:
cleaning the rear surface of the substrate with a brush after the polishing of the rear surface, or after the etching of the film and before the polishing of the rear surface.

3. The substrate processing method of claim 2,
wherein, in the cleaning of the rear surface of the substrate with the brush, the rear surface of the substrate is cleaned with the brush while a cleaning liquid is supplied to the rear surface of the substrate.

4. The substrate processing method of claim 2, further comprising:
cleaning the rear surface of the substrate by supplying a cleaning liquid in a form of mist to the rear surface of the substrate after the cleaning of the rear surface of the substrate with the brush.

5. The substrate processing method of claim 1,
wherein, in the etching of the film, the film is etched such that the film is left on the rear surface of the substrate.

6. The substrate processing method of claim 1,
wherein, in the etching of the film, the film is etched by sequentially supplying multiple chemical liquids to the rear surface of the substrate.

7. The substrate processing method of claim 1,
wherein the film is a silicon nitride film, a silicon oxide film, or a multilayer film including a silicon nitride film and a silicon oxide film.

8-11. (canceled)

12. The substrate processing method of claim 3, further comprising:
cleaning the rear surface of the substrate by supplying a cleaning liquid in a form of mist to the rear surface of the substrate after the cleaning of the rear surface of the substrate with the brush.

13. The substrate processing method of claim 2,
wherein, in the etching of the film, the film is etched such that the film is left on the rear surface of the substrate.

14. The substrate processing method of claim 3,
wherein, in the etching of the film, the film is etched such that the film is left on the rear surface of the substrate.

15. The substrate processing method of claim 4,
wherein, in the etching of the film, the film is etched such that the film is left on the rear surface of the substrate.

16. The substrate processing method of claim 2,
wherein, in the etching of the film, the film is etched by sequentially supplying multiple chemical liquids to the rear surface of the substrate.

17. The substrate processing method of claim 3,
wherein, in the etching of the film, the film is etched by sequentially supplying multiple chemical liquids to the rear surface of the substrate.

18. The substrate processing method of claim 4,
wherein, in the etching of the film, the film is etched by sequentially supplying multiple chemical liquids to the rear surface of the substrate.

19. The substrate processing method of claim 2,
wherein the film is a silicon nitride film, a silicon oxide film, or a multilayer film including a silicon nitride film and a silicon oxide film.

20. The substrate processing method of claim 3,
wherein the film is a silicon nitride film, a silicon oxide film, or a multilayer film including a silicon nitride film and a silicon oxide film.

21. A substrate processing system, comprising:
an etching apparatus configured to etch a film formed on a rear surface of a substrate opposite to a main surface of the substrate; and
a rear surface processing apparatus including a polishing mechanism configured to polish the rear surface of the substrate after the film is etched.

22. The substrate processing system of claim 21, further comprising:
an inverting mechanism configured to invert the substrate,
wherein the etching apparatus etches the film while the main surface of the substrate faces upwards,
the polishing mechanism polishes, after the film is etched, the rear surface of the substrate inverted by the inverting mechanism, and
the inverting mechanism inverts the substrate again after the rear surface of the substrate is polished by the polishing mechanism.

23. The substrate processing system of claim 21,
wherein the rear surface processing apparatus further includes a cleaning mechanism configured to clean, with a brush, the rear surface of the substrate after the rear surface of the substrate is polished by the polishing mechanism, or the rear surface of the substrate after the film is etched by the etching apparatus and before the rear surface of the substrate is polished by the polishing mechanism.

24. The substrate processing system of claim 23, further comprising:
an inverting mechanism configured to invert the substrate,
wherein the etching apparatus etches the film while the main surface of the substrate faces upwards,
the polishing mechanism polishes, after the film is etched, the rear surface of the substrate inverted by the inverting mechanism,
the cleaning mechanism cleans the rear surface of the substrate after the rear surface of the substrate is polished by the polishing mechanism, and
inverting mechanism inverts the substrate again after the rear surface of the substrate is cleaned by the cleaning mechanism.
